(19) United States
(12) Patent Application Publication
(10) Pub. No.: US 2011/0140225 A1
(43) Pub. Date: Jun. 16, 2011

(54) SEMICONDUCTOR DEVICE

(76) Inventor: Masafumi TSUTSUI, Nara (JP)

(21) Appl. No.: 12/950,447

(22) Filed: Nov. 19, 2010

(30) Foreign Application Priority Data
Dec. 16, 2009 (JP) 2009-285231

(51) Int. Cl. H01L 27/146; H01L 31/02

(52) U.S. Cl. 257/440; 257/443; 257/E31.113; 257/E27.134

(57) ABSTRACT

In a first interlevel insulating film, a first region which is made of the first interlevel insulating film and in which first wiring films are not provided is formed to be located above a first light receiving part of the plurality of light receiving parts, and a second region which is made of the first interlevel insulating film and in which the first wiring films are not provided is formed to be located above a second light receiving part of the plurality of light receiving parts which is adjacent to the first light receiving part. A space between ones of the first wiring films with the first region interposed therebetween is larger than a space between ones of the first wiring films with the second region interposed therebetween.

### CROSS-REFERENCE TO RELATED APPLICATION

This application claims priority to Japanese Patent Application No. 2009-285231 filed on Dec. 16, 2009, the disclosure of which including the specification, the drawings, and the claims is hereby incorporated by reference in its entirety.

### BACKGROUND

The present disclosure relates to semiconductor devices, and particularly, relates to a semiconductor device which serves as a solid-state imaging device with backside illumination in which light enters a back surface of a substrate, and allows reduction of optical crosstalk between adjacent pixels.

In recent years, due to the miniaturization of imaging devices in which a semiconductor solid-state imaging device is mounted, the chip area for such semiconductor solid-state imaging devices, such as charge-coupled device (CCD) image sensors, complementary metal oxide semiconductor (CMOS) image sensors, etc., has continued to be reduced, and the number of pixels per chip has been increased. Consequently, the device area per pixel has been reduced and, for example, the device area per pixel is now 2 μm×2 μm or less. In a method in which light is caused to enter through a surface of a chip of a conventional semiconductor solid-state imaging device on which a wiring layer and an electric layer are provided, an area in which light can pass between a wiring and an electrode is small about (≈about 1 μm×1 μm). Thus, light is blocked by the wiring or the electrode, so that sufficiently good light condensing characteristics for condensing light entering the device cannot be achieved. Therefore, there have been attempts to further reduce the size of solid-state imaging devices and increase the number of pixels by employing a solid-state imaging device with backside illumination, in which light enters through a surface of a substrate on which a wiring layer is not formed, to improve the light condensing characteristics.

One of problems of such a solid-state imaging device with backside illumination is optical crosstalk. Specifically, crosstalk is a phenomenon in which light which has entered through a back surface of a substrate toward a specific pixel passes through the substrate to be reflected and scattered at a wiring layer provided on a front surface of the substrate, and thus, the light enters another pixel located adjacent to the pixel toward which the light originally headed and serves as a false signal, resulting in degradation of image quality.

A structure of a typical solid-state imaging device with backside illumination will be described below with reference to FIG. 8 (see, for example, Japanese Patent No. 4123415).

As shown in FIG. 8, light receiving parts 102a and 102b serving as photoelectric conversion regions (photodiodes) are formed in a semiconductor substrate 101. The light receiving part 102a detects short wavelength light, and the light receiving part 102b detects long wavelength light. In the semiconductor substrate 101, an isolation region 103 for defining an element formation region is formed. A gate insulating film 105a and a gate electrode 105b are formed in this order on a front surface of the semiconductor substrate 101, and a sidewall 106 is formed on each side surface of the gate insulating film 105a and the gate electrode 105b. Furthermore, a drain region 104 is formed in a part of the semiconductor substrate 101 located outside and below the gate electrode 105b.

Furthermore, an insulating film 107 is formed entirely over the semiconductor substrate 101 and the isolation region 103, and a wiring layer 108 comprised of wiring films 109 and an insulating film 110a for filling between the wiring films 109 is formed on the insulating film 107. An insulating film 110b is formed on the wiring layer 108, and a wiring layer 111 comprised of wiring films 112 and an insulating film 113a for filling between the wiring films 112 is formed on the insulating film 110b. An insulating film 113b is formed on the wiring layer 111.

A passivation film 114 is formed under a back surface of the semiconductor substrate 101. A color filter 115 which passes short wavelength light and a color filter 116 which passes long wavelength light are formed under the passivation film 114 to be located under the light receiving part 102a and the light receiving part 102b, respectively. An interlevel insulating film 117 is formed under the color filter 115 and the color filter 116. A microlens 118 for short wavelength light and a microlens 119 for long wavelength light are formed under the interlevel insulating film 117 to be located under the color filter 115 and the color filter 116, respectively.

### SUMMARY

Assume that in the solid-state imaging device with backside illumination having the above-described structure, the light receiving parts 102a and 102b are located in an end part of the imaging device chip, and incident light L from a lens (not shown) is oblique. In such a case, it is, in general, difficult to cause the direction of the incident light to be perpendicular to a principal surface of the semiconductor substrate 101, even after the incident light has passed through the microlens 119 for changing the direction of the incident light and condensing light. Consequently, light obliquely enters the light receiving parts 102a and 102b, and, for example, light transmitted through the light receiving part 102b is reflected by the wiring films 109 of the wiring layer 108 located above the semiconductor substrate 101 and reenters the adjacent light receiving part 102a. Similarly, even when light is transmitted through the wiring layer 108, the light might be reflected by the wiring films 112 of the wiring layer 111 and reenter the adjacent light receiving part 102a. In the above-described manner, a problem of optical crosstalk arises.

Furthermore, assuming that the semiconductor substrate is made of silicon, conversion efficiency in converting red light having a wavelength about 650 nm into electrons in the light receiving part is low. Specifically, only 80% of red light is absorbed while the red light moves through a distance of 4 μm. Thus, assuming that, in the above-described conventional structure, the thickness of the light receiving part of the solid-state imaging device with backside illumination is about 3-4 μm, about 20% of red light reaches the wiring layer 111 and is reflected in a pixel adjacent to a pixel which detects red light in the end part of the imaging device chip. Even when the light is transmitted through the wiring layer 108 and is reflected by the wiring layer 111, about 20% of the light is reflected since the insulating film 107 and the insulating films 110a and 110b hardly absorb light. As a result, because a distance between adjacent pixels is about 1 μm, light might reenter the light receiving part, and thus, a problem of optical crosstalk arises.

In view of the foregoing, it is an objective of the present invention to provide a semiconductor device having a structure which allows reduction of optical crosstalk caused by light reflection by a wiring layer even in a pixel located in an end part of a chip of a solid-state imaging device with backside illumination.

To achieve the above-described objective, structures for a semiconductor device according to example aspects of the present invention will be described below.

According to a first aspect of the present invention, a semiconductor device including an imaging area in which a plurality of pixels, each including a light receiving part which performs photoelectric conversion of incident light entering through a first surface of a semiconductor substrate, are arranged in a matrix includes: a first interlevel insulating film formed over a second surface of the semiconductor substrate which is an opposite surface to the first surface; and a first wiring layer including a plurality of first wiring films formed in the first interlevel insulating film, in the first wiring layer, a first region which is made of the first interlevel insulating film and in which the first wiring films are not provided is formed to be located above a first light receiving part of the plurality of light receiving parts, and a second region which is made of the first interlevel insulating film and in which the first wiring films are not provided is formed to be located above a second light receiving part of the plurality of light receiving parts which is adjacent to the first light receiving part, and a space between ones of the first wiring films with the first region interposed therebetween is larger than a space between ones of the first wiring films with the second region interposed therebetween.

The semiconductor device of the first aspect of the present invention may further include: a second wiring layer which includes a plurality of second wiring films and is formed in a second interlevel insulating film provided above the first interlevel insulating film, in the second wiring layer, a third region which is made of the second interlevel insulating film and in which the plurality of the second wiring films are not provided may be formed to be located above the first light receiving part, and a space between ones of the second wiring films with the third region interposed therebetween may be larger than the space between the ones of the first wiring films with the first region interposed therebetween.

The semiconductor device of the first aspect of the present invention may further include: a second wiring layer which includes a plurality of second wiring films and is formed in a second interlevel insulating film provided above the first interlevel insulating film, in the second wiring layer, a third region which is made of the second interlevel insulating film and in which the plurality of the second wiring films are not provided may be formed to be located above the first light receiving part, and a space between ones of the second wiring films with the third region interposed therebetween may be equal to or smaller than the space between the ones of the first wiring films with the first region interposed therebetween.

In the semiconductor device of the first aspect of the present invention, a light blocking film which is not electrically connected may be formed in the second region.

In the semiconductor device of the first aspect of the present invention, a relative position of the first region to the first light receiving part in an end part of the imaging area may be the same as a relative position of the first region to the first light receiving part in a center part of the imaging area.

In the semiconductor device of the first aspect of the present invention, a relative position of the first region to the first light receiving part in an end part of the imaging area may be shifted, as compared to a relative position of the first region to the first light receiving part in a center part of the imaging area, in a direction from the center part to the end part.

In the semiconductor device of the first aspect of the present invention, a light-transmission preventing film may be formed in a part of the front surface of the semiconductor device located above the second light receiving part.

In this case, the light-transmission preventing film may be a silicide film.

In the semiconductor device of the first aspect of the present invention, the first light receiving part may perform photoelectric conversion of relatively long wavelength light, and the second light receiving part may perform photoelectric conversion of relatively short wavelength light.

In this case, the relatively long wavelength light may be red light, and the relatively short wavelength light may be blue or green light.

According to a second aspect of the present invention, a semiconductor device including an imaging area in which a plurality of pixels, each including a light receiving part which performs photoelectric conversion of incident light entering through a first surface of a semiconductor substrate, are arranged in a matrix includes: a first interlevel insulating film formed over a second surface of the semiconductor substrate which is an opposite surface to the first surface; and a first wiring layer including a plurality of first wiring films formed in the first interlevel insulating film, in the first wiring layer, a first region which is made of the first interlevel insulating film and in which the first wiring films are not provided is formed to be located above a first light receiving part of the plurality of light receiving parts, and a relative position of the first region to the first light receiving part in an end part of the imaging area is shifted, as compared to a relative position of the first region to the first light receiving part in a center part of the imaging area, in a direction from the center part to the end part.

In this case, in the first wiring layer, a second region which is made of the first interlevel insulating film and in which the first wiring films are not provided may be formed to be located above a second light receiving part of the plurality of light receiving parts which is adjacent to the first light receiving part, and a light blocking film which is not electrically connected may be formed in the second region.

The semiconductor device of the second aspect of the present invention may further include: a second wiring layer which includes a plurality of second wiring films and is formed in a second interlevel insulating film provided above the first interlevel insulating film, in the second wiring layer, a third region which is made of the second interlevel insulating film and in which the plurality of the second wiring films are not provided may be formed to be located above the first light receiving part, and a relative position of the third region to the first light receiving part in an end part of the imaging area may be shifted, as compared to a relative position of the third region to the first light receiving part in a center part of the imaging area, in a direction from the center part to the end part.

In this case, an amount of a shift of the relative position of the third region may be larger than an amount of a shift of the relative position of the first region.

In the semiconductor device of the second aspect of the present invention, a light-transmission preventing film may be formed in a part of the front surface of the semiconductor device located above the second light receiving part.

In this case, the light-transmission preventing film may be a silicide film.

In the semiconductor device of the second aspect of the present invention, the first light receiving part may perform photoelectric conversion of relatively long wavelength light, and the second light receiving part may perform photoelectric conversion of relatively short wavelength light.

According to a third aspect of the present invention, a semiconductor device including an imaging area in which a plurality of pixels, each including a light receiving part which performs photoelectric conversion of incident light entering through a first surface of a semiconductor substrate, are arranged in a matrix includes: an interlevel insulating film formed over a second surface of the semiconductor substrate which is an opposite surface to the first surface, and a wiring layer including a plurality of wiring films formed in the interlevel insulating film, in the wiring layer, a first region which is made of the interlevel insulating film and in which the wiring films are not provided is formed to be located above a first light receiving part of the plurality of light receiving parts, and a second region which is made of the interlevel insulating film and in which the wiring films are not provided is formed to be located above a second light receiving part of the plurality of light receiving parts which is adjacent to the first light receiving part, and a light-transmission preventing film is formed in a part of the front surface of the semiconductor device located above the second light receiving part.

With each of the above-described structures of the aspect of the present invention, in the end part of the chip, for example, light which is always caused to enter the chip obliquely through the back surface of the semiconductor substrate by a lens of an imaging device can be prevented from being in contact with the first wiring layer after the light has passed through the first light receiving part which absorbs long wavelength light, and can be caused to be transmitted through the interlevel insulating film. As a result, optical crosstalk can be reduced. Also, regardless the center part of the chip or the end part of the chip, when the relative position of the first region to the first light receiving part is not dependent on the pixel position in the chip, the stability of the pattern in lithography in fabrication process steps is improved.

### BRIEF DESCRIPTION OF THE DRAWINGS

FIG. 1A is a cross-sectional view of a center part of a chip of a semiconductor device according to a first example embodiment of the present invention, taken along the line Ia-Ia of FIG. 2. FIG. 1B is a cross-sectional view of an end part of the chip of the semiconductor device of the first example embodiment of the present invention, taken along the line Ib-Ib of FIG. 2.

FIG. 2 is a view illustrating an upper surface of the chip of the semiconductor device according to the first example embodiment of the present invention, when the chip is viewed from the top.

FIG. 3 is a cross-sectional view of an end part of a chip of a semiconductor device according to a variation of the first example embodiment of the present invention.

FIG. 4A is a cross-sectional view of a center part of a chip of a semiconductor device according to a second example embodiment of the present invention, taken along the line IVa-IVa of FIG. 5. FIG. 4B is a cross-sectional view of an end part of the chip of the semiconductor device according to the second example embodiment of the present invention, taken along the line IVb-IVb of FIG. 5.

FIG. 5 is a view illustrating an upper surface of the chip (a front surface of a substrate) of the semiconductor device of the second example embodiment of the present invention, when viewed from the top.

FIG. 6 is a cross-sectional view of an end part of a chip of a semiconductor device according to a variation of the second example embodiment of the present invention.

FIG. 7 is a cross-sectional view of an end part of a chip of a semiconductor device according to a third example embodiment of the present invention.

FIG. 8 is a cross-sectional view of an end part of a chip of a conventional semiconductor device.

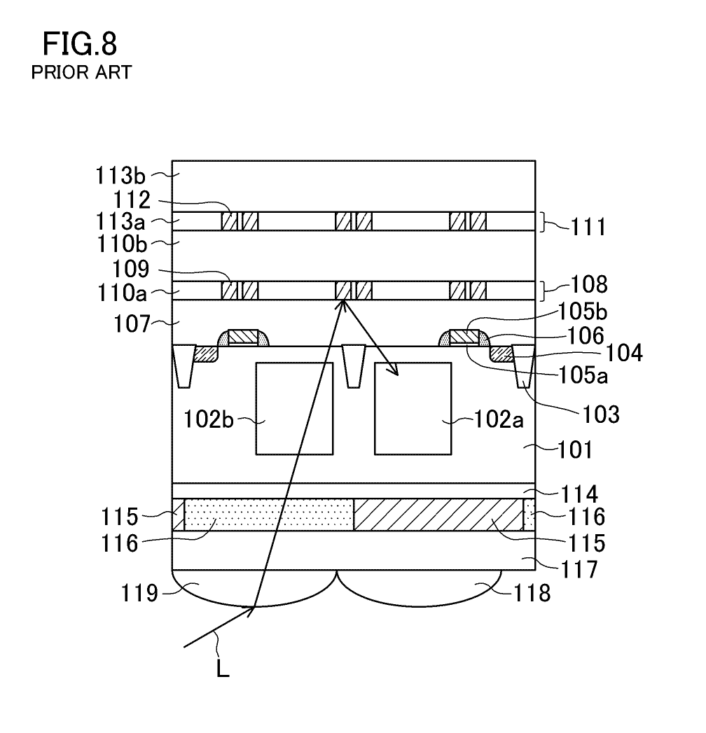

### DETAILED DESCRIPTION

Example embodiments of the present invention will be described with reference to the accompanying drawings. Note that the following embodiments are only for illustrative purposes to clarify technical aspects of the present invention with reference to drawings and detailed description. Those skilled in the art will appreciate preferred embodiments of the present invention and may modify and add variations using the disclosed technique. Such modifications and variations fall within the technical aspects and scope of the invention.

### First Example Embodiment

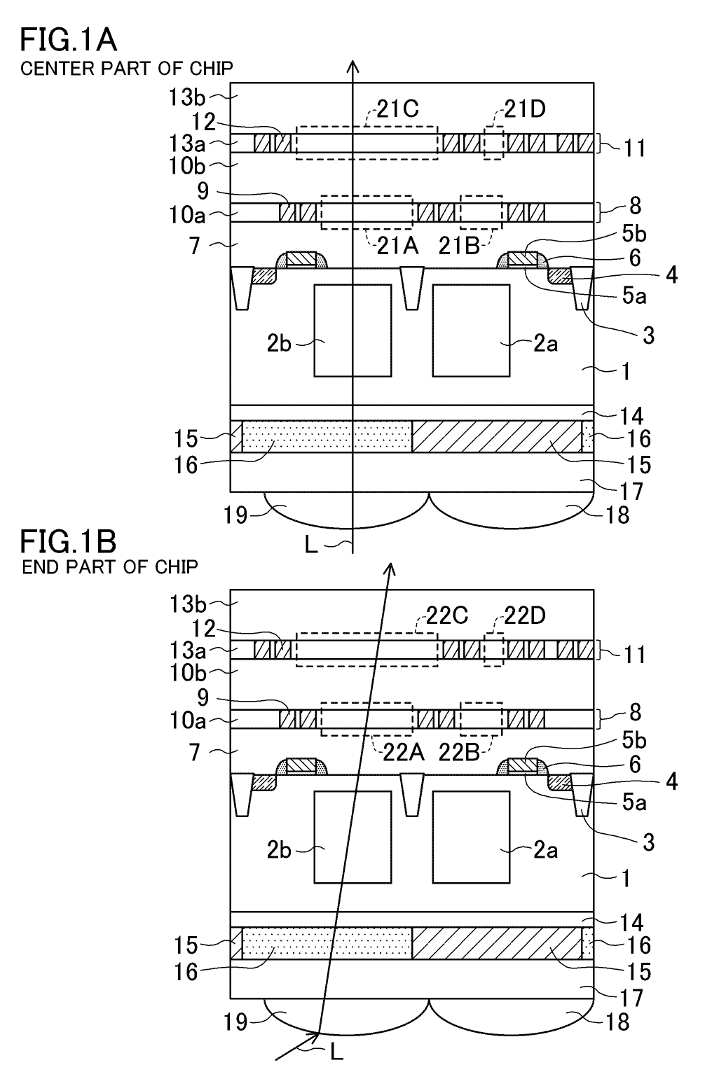

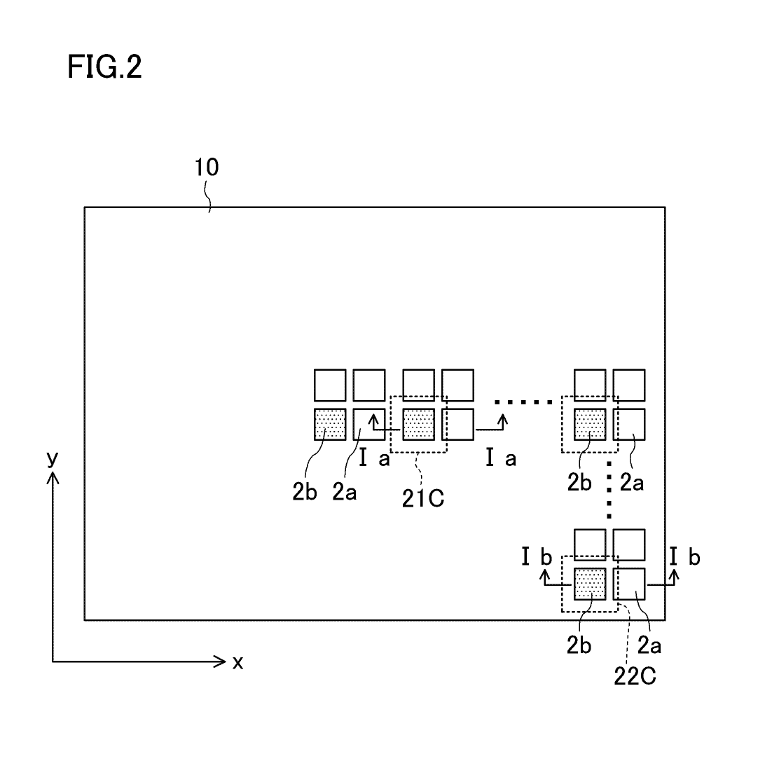

FIG. 1A is a cross-sectional view of a center part of a chip of a semiconductor device according to a first example embodiment of the present invention, taken along the line Ia-Ia of FIG. 2. FIG. 1B is a cross-sectional view of an end part of the chip of the semiconductor device of the first example embodiment of the present invention, taken along the line Ib-Ib of FIG. 2. FIG. 2 is a view illustrating an upper surface of the chip of the semiconductor device according to the first example embodiment of the present invention, when the chip is viewed from the top, i.e., a plan view of the semiconductor device including an imaging area in which a plurality of pixels, each including a light receiving part for performing photoelectric conversion of incident light L entering through a front surface of a substrate are arranged in a matrix.

As shown in FIGS. 1A and 1B, in each of a center part (a central part) and an end part (a peripheral part) of a chip (an imaging area), a light receiving part 2a which serves as a photoelectric conversion region (a photodiode) and is made of an n-type doped region absorbing short wavelength light to perform photoelectric conversion, and a light receiving part 2b which serves as a photoelectric conversion region and is made of an n-type doped region absorbing long wavelength light to perform photoelectric conversion are formed in a p-type semiconductor substrate 1 made of, for example, silicon. An isolation region 3 which is made of, for example, an oxide film and defines an element formation region is formed in a front surface (a second surface) of the semiconductor substrate 1. A gate insulating film 5a made of, for example, a silicon oxide film, and a gate electrode 5b made of a conductive material such as, for example, silicon and metal (e.g., Al, W, Ti, TiN, and TaN) are formed in this order on the front surface of the semiconductor substrate 1. A sidewall 6 made of, for example, a silicon oxide film is formed on each side surface of each of the gate insulating film 5a and the gate electrode 5b. Furthermore, a drain region 4 made of an n-type doped region is formed in a part of the semiconductor substrate 1 located outside and below of the gate electrode 5b. As described above, a read transistor is formed in the element formation region defined by the isolation region 3.

Furthermore, an insulating film 7 such as, for example, a silicon oxide film and a borophosphosilicate glass (BPSG) film is formed entirely over the semiconductor substrate 1 and the isolation region 3 to cover the read transistor. A wiring layer (a first wiring layer) 8 comprised of wiring films 9 made of a conductive material such as, for example, Al and Cu, and an insulating film 10a made of, for example, a silicon oxide film or a BPSG film and filling between the wiring films 9 is formed on the insulating film 7. An insulating film 10b made of, for example, a silicon oxide film or a BPSG film is formed on the wiring layer 8. A wiring layer (a second wiring layer) 11 comprised of wiring films 12 made of a conductive material such as, for example, Al and Cu, and an insulating film 13a made of, for example, a silicon oxide film or a BPSG film and filling between the wiring films 12 is formed on the insulating film 10b. An insulating film 13b made of, for example, a silicon oxide film or a BPSG film is formed on the wiring layer 11.

A passivation film 14 made of, for example, an oxide film, is formed under a back surface (a first surface) of the semiconductor substrate 1. A color filter 15 which passes short wavelength light and a color filter 16 which passes long wavelength light are formed under the passivation film 14 to be located under the light receiving part 2a and the light receiving part 2b, respectively. An interlevel insulating film 17 made of, for example, a silicon oxide film or a BPSG film is formed under the color filters 15 and 16. A microlens 18 which is for short wavelength light and is made of, for example, acryl resin or fluoride resin, and a microlens 19 which is for long wavelength light and is made of, for example, acryl resin or a fluoride resin are formed under the interlevel insulating film 17 to be located under the color filter 15 and the color filter 16, respectively.

In this case, as shown in FIG. 1A, in the center part of the chip, a region 21B and a region 21A in which the wiring films 9 are not formed and each of which is made of the insulating film 10a (the first interlevel insulating film) and located between ones of the wiring films 9 are formed in the wiring layer 8 to be located above the light receiving part 2a and the light receiving part 2b, respectively. Also, a region 21D and a region 21C in which the wiring films 12 are not formed and each of which is made of the insulating film 13a (the second interlevel insulating film) and located between ones of the wiring films 12 are formed in the wiring layer 11 to be located above the light receiving part 2a and light receiving part 2b, respectively. Similarly, as shown in FIG. 1B, in the end part of the chip, a region 22B and a region 22A in which the wiring films 9 are not formed and each of which is made of the insulating film 10a and located between ones of the wiring films 9 are formed in the wiring layer 8 to be located above the light receiving part 2a and light receiving part 2b, respectively. Also, a region 22D and a region 22C in which the wiring films 12 are not formed and each of which is made of the insulating film 13a and located between ones of the wiring films 12 are formed in the wiring layer 11 to be located above the light receiving part 2a and the light receiving part 2b, respectively.

In the wiring layer 8, a space between the ones of the wiring films 9 which face one another in the end part of the chip and between which the region 22A made of the insulating film 10a and located above the light receiving part 2b is interposed is larger than a space between the ones of wiring films 9 which face one another in the end part of the chip and between which the region 22B made of the insulating film 10a and located above the light receiving part 2a is interposed. In this case, similarly, in the wiring layer 8, a space between the ones of the wiring films 9 which face one another in the center part of the chip and between which the region 21A made of the insulating film 10a and located above the light receiving part 2b is interposed is also larger than a space between the ones of the wiring films 9 which face one another in the center part of the chip and between which the region 21B made of the insulating film 10a and located above the light receiving part 2a is interposed. That is, regardless of the center part of the chip or the end part of the chip (without depending on a pixel position), a width of each of the regions (21A, 22A) located above the light receiving part 2b absorbing long wavelength light in each pixel is larger than a width of each of the regions 21B and 22B located above the adjacent light receiving part 2a absorbing short wavelength light in the same manner.

Furthermore, it is preferable that, in the wiring layer 11, a space between the ones of the wiring films 12 which face one another in the end part of the chip and between which the region 22C made of the insulating film 13a and located above the light receiving part 2b is interposed is larger than a space between the ones of the wiring films 12 which face one another in the end part of the chip and between which the region 22D made of the insulating film 13a and located above the light receiving part 2a is interposed. In this case, similarly, in the wiring layer 11, a space between the ones of the wiring films 12 which face one another in the center part of the chip and between which the region 21C made of the insulating film 13a and located above the light receiving part 2b is interposed is also larger than a space between the ones of the wiring films 12 which face one another in the center part of the chip and between which the region 21D made of the insulating film 13a and located above the light receiving part 2a is interposed. That is, regardless of the center part of the chip or the end part of the chip (without depending on a pixel position), a width of each of the regions (21C, 22C) located above the light receiving part 2b absorbing long wavelength light in each pixel is larger than a width of each of the regions 21D and 22D located above the adjacent light receiving part 2a absorbing short wavelength light in the same manner.

Moreover, it is more preferable that the space between the ones of the wiring films 12 which face one another in the end part of the chip and between which the region 22C made of the insulating film 13a and located above the light receiving part 2b is interposed is larger than the space between the ones of the wiring films 9 which face one another in the end part of the chip and between which the region 22A made of the insulating film 10a and located above the light receiving part 2b is interposed. In this case, similarly, it is more preferable that the space between the ones of the wiring films 12 which face one another in the center part of the chip and between which the region 21C made of the insulating film 13a and located above the light receiving part 2b is interposed is larger than the space between the ones of the wiring films 9 which face one another in the center part of the chip and between which the region 21A made of the insulating film 10a and located above the light receiving part 2b is interposed. As described above, it is preferable that the space between the ones of the wiring films 12 which face one another in the end part of the chip and between which the region 22C made of the insulating film 13a located above the light receiving part 2b is interposed is larger than the space between the ones of the wiring films 9 which face one another in the end part of the chip and between which the region 22A made of the insulating film 10a and located above the light receiving part 2b is interposed. However, the space between the ones of the wiring films 12 which face one another in the end part of the chip and between which the region 22C made of the insulating film 13a and located above the light receiving part 2b is interposed may be equal to or smaller than the space between the ones of the wiring films 9 which face one another in the end part of the chip and between which the region 22A made of the insulating film 10a and located above the light receiving part 2b is interposed. Similarly, the space between the ones of the wiring films 12 which face one another in the center part of the chip and between which the region 21C made of the insulating film 13a and located above the light receiving part 2b is interposed may be equal to or smaller than the space between the ones of the wiring films 9 which face one another in the center part of the chip and between which the region 21A made of the insulating film 10a and located above the light receiving part 2b is interposed.

Considering that incident light obliquely enters the chip in the end part of the chip, according to this example embodiment, the region 22A made of the insulating film 10a and the region 22C made of the insulating film 13a which are formed in parts of the wiring layer 8 and the wiring layer 11 located in the end part of the chip can be shifted in a direction from the center part of the chip to the end part of the chip, and the region 21C made of the insulating film 13a and the region 22A made of the insulating film 10a which are formed in parts of the wiring layer 8 and the wiring layer 11 located in the center part of the chip can be shifted by the same shift amount as the shift amount in the end part of the chip in a direction from the center part of the chip to the end part of the chip.

The space between the ones of the wiring films 12 which face one another in the end part of the chip and between which the region 22D made of the insulating film 13a and located above the light receiving part 2a is interposed is smaller than the space between the ones of the wiring films 9 which face one another in the end part of the chip and between which the region 22B made of the insulating film 10a and located above the light receiving part 2a is interposed. In this case, similarly, the space between the ones of the wiring films 12 which face one another in the center part of the chip and between which the region 21D made of the insulating film 13a and located above the light receiving part 2a is interposed is smaller than the space between the ones of the wiring films 9 which face one another in the center part of the chip and between which the region 21B made of the insulating film 10a and located above the light receiving part 2a is interposed.

As can be seen from FIG. 2 illustrating the overall view of the chip 10 in which a plurality of pixels are arranged in a matrix, as described above, regardless of the end part of the chip or the center part of the chip, the widths of the region 21C and the region 22C in the wiring layer 11, each of which is made of the insulating film 13a and located above the corresponding light receiving part 2b, are uniform. Although not shown in FIG. 2, the widths of the region 21A and the region 22A in the wiring layer 8, each of which is made of the insulating film 10a and located above the corresponding light receiving part 2b, are uniform, and are smaller than the widths of the region 21C and the region 22C in the wiring layer 11, each of which is made of the insulating film 13a and located above the corresponding light receiving part 2b.

With the above-described structure, in the end part of the chip, light which is inevitably caused to enter the chip obliquely through the back surface of the semiconductor substrate 1 by the lens of the imaging device can be prevented from being in contact with the wiring layers 8 and 11 after the light has passed through the light receiving part 2b, and can be caused to be transmitted through the insulating films 7, 10a, 10b, 13a, and 13b. As a result, optical crosstalk can be reduced. Also, as described above, the relative position of each of the regions (21C, 21A, 22C, and 22A), each of which is made of the insulating film 10a or 13a and located above the corresponding light receiving part 2b, to the light receiving part 2b, and the relative position of each of the regions (21D, 21B, 22D, and 22B), each of which is made of the insulating film 10a or 13a and located above the corresponding light receiving part 2a, to the light receiving part 2a are not dependent on the pixel position in the chip, and therefore, the stability of the pattern in lithography in fabrication process steps etc. are improved.

Note that an amount by which the width of each of the regions 22A and 21A formed in parts of the wiring layer 8 located in the end part and the center part of the chip, each of which is made of the insulating film 10a and located above the corresponding light receiving part 2b is larger than the width of each of the regions 22B and 21B formed in parts of the wiring layer 8 located in the end part and the center part of the chip, each of which is made of the insulating film 10a and located above the corresponding light receiving part 2a has to be about twice a shift amount dx1 in the lateral direction and about twice a shift amount dy1 in the longitudinal direction, which will be described in a second example embodiment below. Similarly, an amount by which the width of each of the regions 22C and 21C formed in parts of the wiring layer 11 located in the end part and the center part of the chip, each of which is made of the insulating film 13a and located above the corresponding light receiving part 2b is larger than the width of each of the regions 22D and 21D formed in parts of the wiring layer 11 located in the end part and the center part of the chip, each of which is made of the insulating film 13a and located above the corresponding light receiving part 2a has to be about twice a shift amount dx2 in the lateral direction and about twice a shift amount dy2 in the longitudinal direction.

Variation

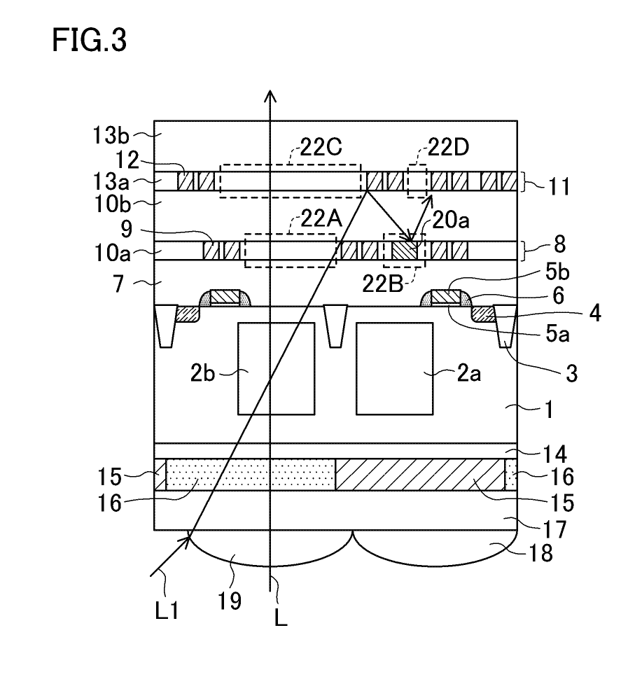

FIG. 3 is a cross-sectional view illustrating an end part of a chip of a semiconductor device according to a variation of the first example embodiment of the present invention. Specifically, as compared to the structure of FIG. 1B, the structure of FIG. 3 is different in that, in the end part of the chip, a light-blocking film (light-transmission preventing film) 20a which is not electrically connected (not active) is formed in the region 22B in the wiring layer 8, which is made of the insulating film 10a and located above the light receiving part 2a, using the same film as the wiring films 9. Each of the other parts has the same structure as that of the structure of FIG. 1B. Note that the light-blocking film 20a may be divided into a plurality of pieces.

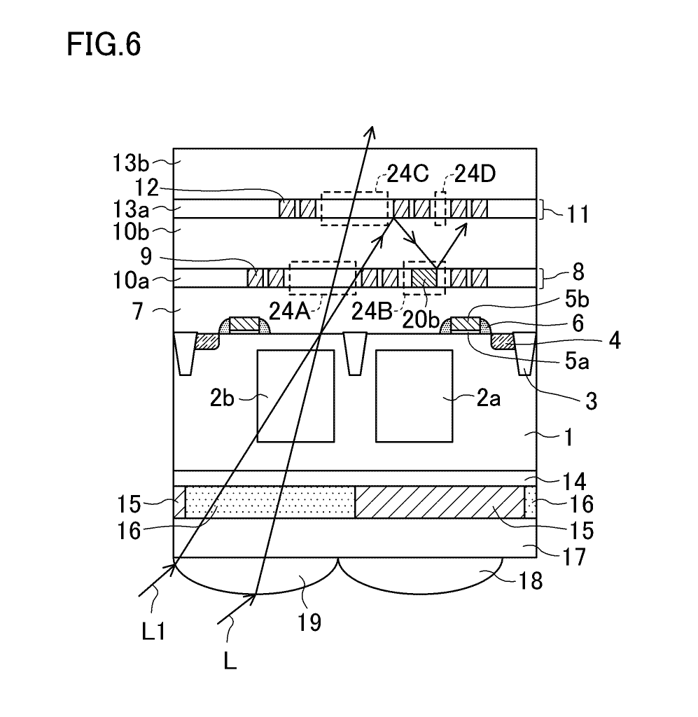

Thus, advantageously, optical crosstalk due to incident light such as incident light L1 can be more effectively reduced while simplifying fabrication process steps. Also, as shown in FIG. 6 which will be described below, the generation of crystal defects etc. caused by providing a silicide layer above a light receiving part is prevented, so that a more accurate image can be obtained. This structure is particularly effective when the chip has a thickness (for example, a thickness larger than 1 μm) which does not allow short wavelength light for which the semiconductor substrate 1 has a large absorption coefficient to reach the wiring layers 8 and 11.

In the above-described example embodiment, if color filters in respective upper parts of pixels provided in the chip are set so that each of the color filters mainly detects one of red light (with a wavelength of about 650 nm), blue light (with a wavelength of about 450 nm), and green light (with a wavelength of about 530 nm), and the pixels are arranged in a Bayer matrix, the light receiving parts 2b which detect long wavelength light are red pixels whose mainly detected light has a longer wavelength than wavelengths of light beams mainly detected by other pixels, and each of which is adjacent a green pixel.

Note that each of the microlenses 18 and 19 may have different curvatures for light beams having different wavelengths. Also, in general, to improve the light condensing characteristics for condensing light at the light receiving parts 2a and 2b, the relative positions of the microlenses 18 and 19 to the light receiving parts 2a and 2b vary between the center part of the chip and the end part of the chip. Even in such a case, the present invention is effective.

Note that, when viewed from the top, the area of each of the light receiving parts 2a and 2b is, in general, about 1 μm×1 μm, and the area of each of the regions 21A, 21C, 22A, and 22C, which is located above the light receiving part 2b and in which a wiring is not provided is preferably 50% or more of the area of each of the light receiving parts 2a and 2b, and is more preferably 80-100% thereof.

### Second Embodiment

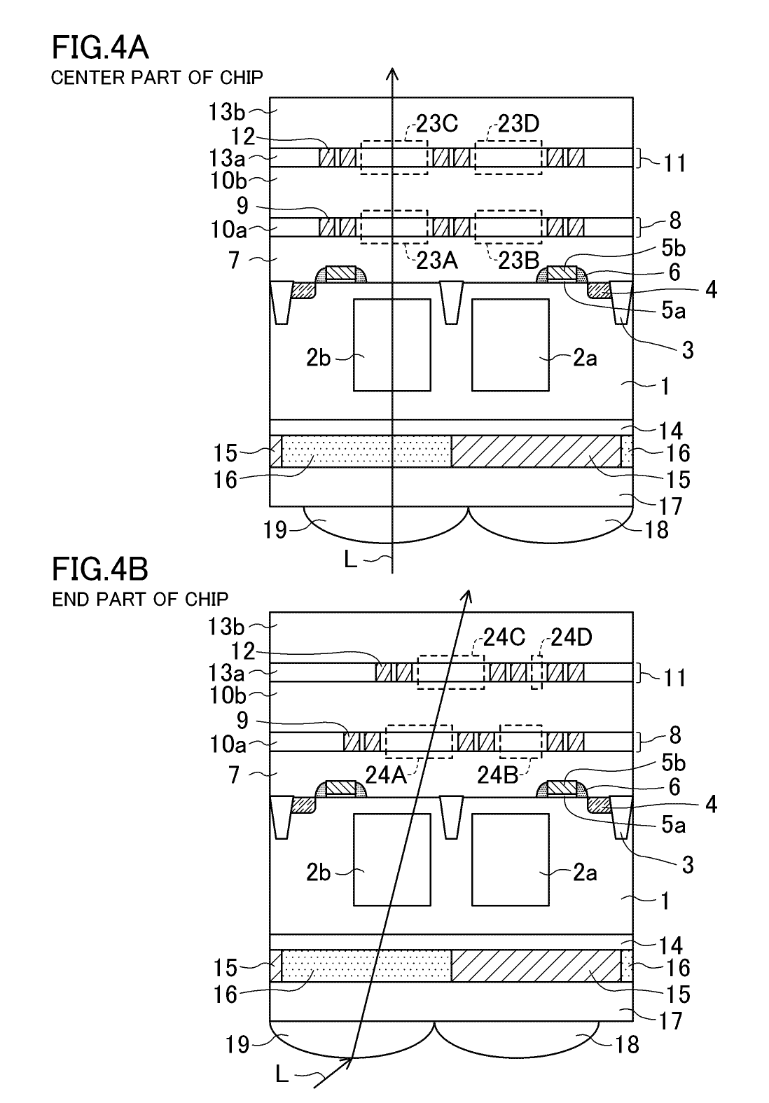

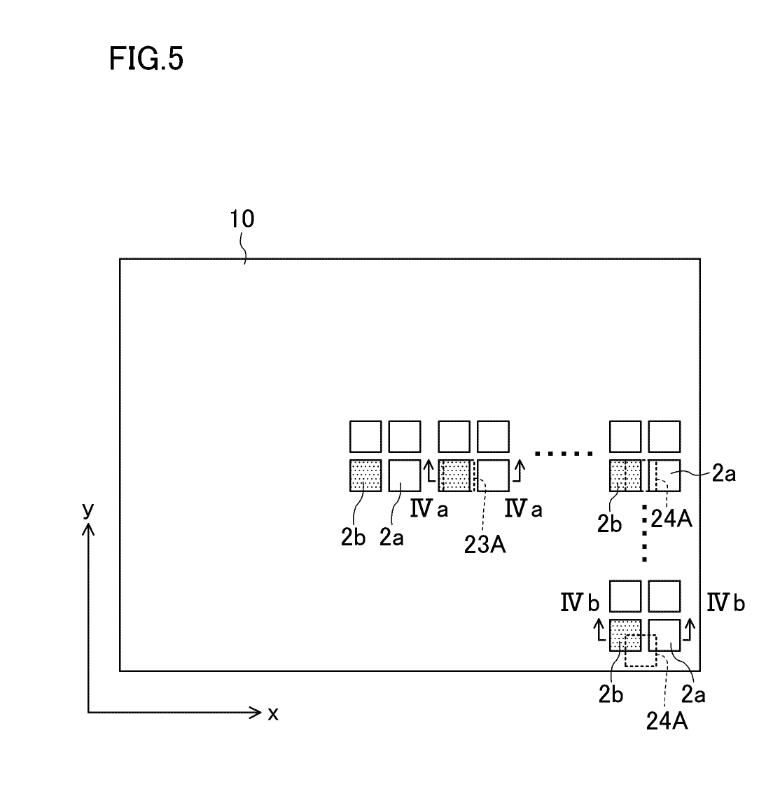

FIG. 4A is a cross-sectional view of a center part (a central part) of a chip of a semiconductor device according to a second example embodiment of the present invention, taken along the line IVa-IVa of FIG. 5. FIG. 4B is a cross-sectional view of an end part (a peripheral part) of the chip of the semiconductor device according to the second example embodiment of the present invention, taken along the line IVb-IVb of FIG. 5. FIG. 5 is a view illustrating an upper surface of the chip (a front surface of a substrate) of the semiconductor device according to the second example embodiment of the present invention, when the chip is viewed from the top, i.e., a plan view of the semiconductor device including an imaging area in which a plurality of pixels, each including a light receiving part for performing photoelectric conversion of incident light L entering through the front surface of the substrate, are arranged in a matrix.

As shown in FIGS. 4A and 4B, in each of a center part and an end part of a chip, a light receiving part 2a which serves as a photoelectric conversion region (a photodiode) and is made of an n-type doped region absorbing short wavelength light to perform photoelectric conversion, and a light receiving part 2b which serves as a photoelectric conversion region and is made of an n-type doped region absorbing long wavelength light to perform photoelectric conversion are formed in a p-type semiconductor substrate 1 made of, for example, silicon. An isolation region 3 which is made of, for example, an oxide film and defines an element formation region is formed in a front surface of the semiconductor substrate 1. A gate insulating film 5a made of, for example, a silicon oxide film, and a gate electrode 5b made of a conductive material such as, for example, silicon and metal (e.g., Al, W, Ti, TiN, and TaN) are formed in this order on the front surface (a second surface) of the semiconductor substrate 1. A sidewall 6 made of, for example, a silicon oxide film is formed on each side surface of each of the gate insulating film 5a and the gate electrode 5b. Furthermore, a drain region 4 made of an n-type doped region is formed in a part of the semiconductor substrate 1 located outside and below of the gate electrode 5b. As described above, a read transistor is formed in the element formation region defined by the isolation region 3.

Furthermore, an insulating film 7 such as, for example, a silicon oxide film and a borophosphosilicate glass (BPSG) film is formed entirely over the semiconductor substrate 1 and the isolation region 3 to cover the read transistor. A wiring layer (a first wiring layer) 8 comprised of wiring films 9 made of a conductive material such as, for example, Al and Cu, and an insulating film 10a made of such as, for example, a silicon oxide film and a BPSG film and filling between the wiring films 9 is formed on the insulating film 7. An insulating film 10b made of, for example, a silicon oxide film or a BPSG film is formed on the wiring layer 8. A wiring layer (a second wiring layer) 11 comprised of wiring films 12 made of a conductive material such as, for example, Al and Cu, and an insulating film 13a made of, for example, a silicon oxide film or a BPSG film and filling between the wiring films 12 is formed on the insulating film 10b. An insulating film 13b made of, for example, a silicon oxide film or BPSG film is formed on the wiring layer 11.

A passivation film 14 made of, for example, an oxide film is formed under a back surface (a first surface) of the semiconductor substrate 1. A color filter 15 which passes short wavelength light and a color filter 16 which passes long wavelength light are formed under the passivation film 14 to be located under the light receiving part 2a and the light receiving part 2b, respectively. An interlevel insulating film 17 made of, for example, a silicon oxide film or a BPSG film is formed under the color filters 15 and 16. A microlens 18 which is for short wavelength light and is made of, for example, acryl resin or fluoride resin, and a microlens 19 which is for long wavelength light and is made of, for example, acryl resin or a fluoride resin are formed under the interlevel insulating film 17 to be located under the color filter 15 and the color filter 16, respectively.

In this case, as shown in FIG. 4A, in the center part of the chip, a region 23B and a region 23A in which the wiring films 9 are not formed and each of which is made of the insulating film 10a (the first interlevel insulating film) and located between ones of the wiring films 9 are formed in the wiring layer 8 to be located above the light receiving part 2a and the light receiving part 2b, respectively. Also, a region 23D and a region 23C in which the wiring films 12 are not formed and each of which is made of the insulating film 13a (the second interlevel insulating film) and located between ones of the wiring films 12 are formed in the wiring layer 11 to be located above the light receiving part 2a and light receiving part 2b, respectively. Similarly, as shown in FIG. 4B, in the end part of the chip, a region 24B and a region 24A in which the wiring films 9 are not formed and each of which is made of the insulating film 10a and located between ones of the wiring films 9 are formed in the wiring layer 8 to be located above the light receiving part 2a and light receiving part 2b, respectively. Also, a region 24D and a region 24C in which the wiring films 12 are not formed and each of which is made of the insulating film 13a and located between ones of the wiring films 12 are formed in the wiring layer 11 to be located above the light receiving part 2a and the light receiving part 2b, respectively.

In the wiring layer 8, the relative position of the region 24A in the end part of the chip, which is made of the insulating film 10a and located above the light receiving part 2b, to the light receiving part 2b is shifted in the direction from the center of the chip to the end part of the chip, as compared to the relative position of the region 23A in the center part of the chip, which is made of the insulating film 10a and located above the light receiving part 2b. Preferably, in the wiring layer 11, the relative position of the region 24C in the end part of the chip, which is made of the insulating film 13a and located above the light receiving part 2b, to the light receiving part 2b is shifted in the direction from the center of the chip to the end part of the chip, as compared to the relative position of the region 23C in the center part of the chip, which is made of the insulating film 13a and located above the light receiving part 2b. More preferably, the amount of the shift in the wiring layer 11 is larger than the amount of the shift in the wiring layer 8. As a result of the above-described shifts of the relative positions of the regions 24A and 24C in the end part of the chip, each of which is made of insulating film 10a or insulating film 13a and located above the corresponding light receiving part 2b, to the light receiving part 2b, each of the regions 24B and 24D located adjacent to the regions 24A and 24C, respectively, is smaller than an associated one of the regions 24A and 24C.

As can be seen from FIG. 5 illustrating the overall view of the chip 10 in which the plurality of pixels are arranged in a matrix, as described above, the relative position of the region 24A in the end part of the chip, which is made of the insulating film 10a and located above the light receiving part 2b, to the light receiving part 2b is shifted in the direction from the center part of the chip to the end part of the chip, as compared to the relative position of the region 23A in the center part of the chip, which is made of the insulating film 10a and located above the light receiving part 2b, to the light receiving part 2b.

With the above-described structure, in the end part of the chip, light which is always caused to enter the chip obliquely through the back surface of the semiconductor substrate 1 by the lens of the imaging device can be prevented from being in contact with the wiring layers 8 and 11 after the light has passed through the light receiving part 2b, and can be caused to be transmitted through the insulating films 7, 10a, 10b, 13a, and 13b. As a result, optical crosstalk can be reduced.

In this case, the shift amount dx1 in the lateral direction and the shift amount dy1 in the longitudinal direction between the regions 23A and 24A in the wiring layer 8, each of which is made of insulating film 10a, can be expressed by the following expressions using x and y which indicate the position of each pixel in the chip.

dx1=ax+b

a≧0

dy1=cy+d

c≧0, c≈a

Note that it can be roughly determined that dx1=dy1=0 holds in the center part of the chip. Each of coefficients a, b, c, and d can be determined by considering the optical system including the lens of the imaging device and the microlens of the solid-state imaging device in terms of ray optics, wave optics, and electromagnetic wave optics.

Assume that a distance from a lens of the imaging device to a solid-state imaging device is s, and the size of the solid-state imaging device chip is t. Then, an incident angle u of light entering the light receiving part in the end part of the chip is at least

u=arctan(t/2s)

In general, the incident angle is changed by a microlens to be closer to a perpendicular angle to the semiconductor substrate 1. In this case, assuming that a focus point of the microlens is at the front surface of the semiconductor substrate 1, when the distance from the front surface of the semiconductor substrate 1 to the wiring layer 8 is S, and the incident angle of incident light from the microlens in a pixel in the chip is θ, a difference dd1 in shift amount between the center part of the chip and the position of the pixel in the chip is approximately

dd1=S×tan(θ)

and the following approximate relationship is observed.

dd1×dd1≈dx1×dx1+dy1×dy1

For example, if it is assumed that, in the end part of the chip, the incident angle θ=20°, and S=300 nm, the relative position of the region 24A to the light receiving part 2b in the end part of the chip has to be shifted by about 109 nm, as compared to the relative position of the region 23A to the light receiving part 2b in the center part of the chip. In this case, it has been assumed that the focus point of the microlens 19 is at the front surface of the semiconductor substrate 1. If, in general, the distance from the focus point to the wiring layer 8 is S2, the relative position of the region 24A to the light receiving part 2b in the end part of the chip has to be shifted by about an amount of

dd1=S2×tan(θ)

Therefore, in a pixel in the end part of the chip, the relative position of the region 24A to the light receiving part 2b has to be shifted by about 0.05-1 μm according to the angle of incident light entering a pixel in the center part of the chip. Since the distance to an adjacent light receiving part is, in general, about 1-2 μm, and each of the wiring width and the space between wirings is about 0.05-0.1 μm, the wiring position can be easily shifted by 0.05-1 μm.

Similarly, the shift amount dx2 in the lateral direction and the shift amount dy2 in the longitudinal direction between the regions 23C and 24C in the wiring layer 11, each of which is made of insulating film 13a, can be expressed by the following expressions using x and y which indicate the position of each pixel in the chip.

dx2=ex+f

e≧0, e≧a

dy2=gy+h

g≧0, g≧c, e≈g

Note that it can be roughly determined that dx2=dy2=0 holds in the center part of the chip. Each of coefficients e, f, g, and h can be determined by analyzing an optical system including a lens of an imaging device and a microlens of a solid-state imaging device using ray optics analysis, wave optics analysis, and electromagnetic wave optics analysis. Furthermore, advantageously, if the shift amounts dx2 and dy2 in the wiring layer 11 are larger than the shift amounts dx1 and dy1 in the wiring layer 8 so that the region 24C is shifted further toward the end of the chip, the contact of oblique incident light with the wiring films 12 in the wiring layer 11 is further reduced. In this case, when the distance between the wiring layer 8 and the wiring layer 11 in the height direction is about 0.3 μm, the difference between the shift amount in the wiring layer 8 and the shift amount in the wiring layer 11 in an pixel in the end part has to be about 0.02-0.3 μm according to the angle of the incident light.

Note that, in the above-described example embodiments, only the case where only the regions in the wiring layers 8 and 11 in which the wiring films 9 and 12 are not formed and each of which is located above the corresponding light receiving part 2b which detects long wavelength light are shifted toward the end part of the chip depending on the position of the pixel in the chip has been described. However, even when the regions in the wiring layers 8 and 11 in which the wiring films 9 and 12 are not formed and each of which is located above the corresponding light receiving part 2a which detects short wavelength light are also shifted in a similar manner, optical crosstalk caused by the light receiving part 2a which detects short wavelength light can be reduced although the light transmission amount is very low.

Variations

FIG. 6 is a cross-sectional view of an end part of a chip of a semiconductor device according to a variation of the second example embodiment of the present invention. Specifically, as compared to the structure of FIG. 4B, the structure shown in FIG. 6 is different in that, in the end part of the chip, a light blocking film (light-transmission preventing film) 20b which is not electrically connected (not active) is formed in the region 24B in the wiring layer 8, which is made of the insulating film 10a and located above the light receiving part 2a, using the same film as the wiring films 9. Each of the other parts has the same structure as that of the structure of FIG. 4B. Note that the light-blocking film 20b may be divided into a plurality of pieces.

Thus, advantageously, optical crosstalk due to incident light such as incident light L1 can be more effectively reduced while simplifying fabrication process steps. Also, as shown in FIG. 6 which will be described below, the generation of crystal defects etc. caused by providing a silicide layer above a light receiving part is prevented, so that more accurate image can be obtained. This structure is particularly effective when a chip having a thickness (for example, a thickness larger than 1 μm) which does not allow short wavelength light for which the semiconductor substrate 1 has a large absorption coefficient to reach the wiring layers 8 and 11 is used.

In the above-described example embodiment, if color filters in respective upper parts of pixels provided in the chip are set so that each of the color filters mainly detects one of red light (with a wavelength of about 650 nm), blue light (with a wavelength of about 450 nm), and green light (with a wavelength of about 530 nm), the light receiving parts 2b which detect long wavelength light are light receiving parts of red pixels, or red and green pixels, whose mainly detected light has a longer wavelength than wavelengths of light beams mainly detected by other pixels. Similarly, when pixels which mainly detect white light (any visible light) are provided in the chip, the light receiving parts 2b are white pixels, white and red pixels, or white, red and green pixels.

Note that even when color filters are not provided under the light receiving parts 2a and 2b and there is no difference between the wavelengths detected by the pixels, optical crosstalk can be reduced by shifting a region in an upper part of each pixel in the end part of the chip, in which a wiring is not provided, toward the end of the chip.

Note that each of the microlenses 18 and 19 may have different curvatures for light beams having different wavelengths. Also, in general, to improve the light condensing characteristics for condensing light at the light receiving parts 2a and 2b, the relative positions of the microlenses 18 and 19 to the light receiving parts 2a and 2b vary between in the center part of the chip and the end part of the chip. Even in such a case, the present invention is effective.

Note that, when viewed from the top, the size of each of the light receiving parts 2a and 2b is, in general, about 1 μm×1 μm, and the area of each of the regions 23A, 23C, 24A, and 24C which is located above the light receiving part 2b and in which no wiring is provided is preferably 50% or more of the area of each of the light receiving parts 2a and 2b and is more preferably 80-100% thereof.

### Third Embodiment

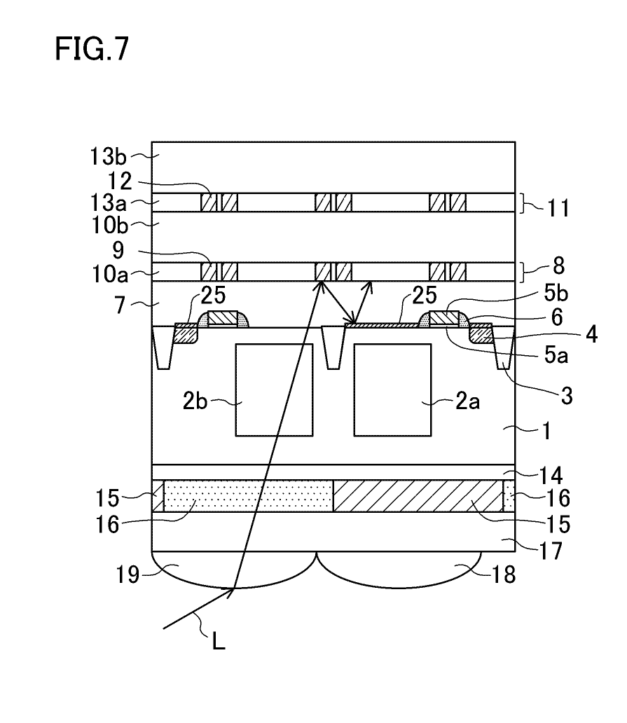

FIG. 7 is a cross-sectional view of an end part (a peripheral part) of a chip of a semiconductor device according to a third example embodiment of the present invention.

As show in FIG. 7, in an end part of a chip, a light receiving part 2a which serves as a photoelectric conversion region (a photodiode) and is made of an n-type doped region absorbing short wavelength light to perform photoelectric conversion, and a light receiving part 2b which serves as a photoelectric conversion region and is made of an n-type doped region absorbing long wavelength light to perform photoelectric conversion are formed in a p-type semiconductor substrate 1 made of, for example, silicon. An isolation region 3 which is made of, for example, an oxide film and defines an element formation region is formed in a front surface (a second surface) of the semiconductor substrate 1. A gate insulating film 5a made of, for example, a silicon oxide film, and a gate electrode 5b made of a conductive material such as, for example, silicon and metal (e.g., Al, W, Ti, TiN, and TaN) are formed in this order on the front surface of the semiconductor substrate 1. A sidewall 6 made of, for example, a silicon oxide film is formed on each side surface of each of the gate insulating film 5a and the gate electrode 5b. Also, a drain region 4 made of an n-type doped region is formed in a part of the semiconductor substrate 1 located outside and below of the gate electrode 5b. As described above, a read transistor is formed in the element formation region defined by the isolation region 3. Furthermore, a metal film 25 made of, for example, silicide (e.g., CoSi₂, NiSi₂, and TiSi₂) is formed on a part of a front surface of the semiconductor substrate 1 located above the light receiving part 2a, and the drain region 4.

Furthermore, an insulating film 7 such as, for example, a silicon oxide film and a borophosphosilicate glass (BPSG) film is formed entirely over the semiconductor substrate 1 and the isolation region 3 to cover the read transistor. A wiring layer (a first wiring layer) 8 comprised of wiring films 9 made of a conductive material such as, for example, Al and Cu, and an insulating film 10a made of such as, for example, a silicon oxide film and a BPSG film and filling between ones of the wiring films 9 is formed on the insulating film 7. An insulating film 10b made of, for example, a silicon oxide film or a BPSG film is formed on the wiring layer 8. A wiring layer (a second wiring layer) 11 comprised of wiring films 12 made of a conductive material such as, for example, Al and Cu, and an insulating film 13a made of, for example, a silicon oxide film or a BPSG film and filling between the wiring films 12 is formed on the insulating film 10b. An insulating film 13b made of, for example, a silicon oxide film or a BPSG film is formed on the wiring layer 11.

On the other hand, a passivation film 14 made of, for example, an oxide film is formed under a back surface (a first surface) of the semiconductor substrate 1. A color filter 15 which passes short wavelength light and a color filter 16 which passes long wavelength light are formed under the passivation film 14 to be located under the light receiving part 2a and the light receiving part 2b, respectively. An interlevel insulating film 17 made of, for example, a silicon oxide film or a BPSG film is formed under the color filters 15 and 16. A microlens 18 which is for short wavelength light and is made of, for example, acryl resin or fluoride resin, and a microlens 19 which is for long wavelength light and is made of, for example, acryl resin or a fluoride resin are formed under the interlevel insulating film 17 to be located under the color filter 15 and the color filter 16, respectively.

In this case, as shown in FIG. 7, in the end part of the chip, as described above, the metal film 25 made of, for example, silicide is formed as light-transmission preventing film on the part of the front surface of the semiconductor substrate 1 located above the light receiving part 2a which absorbs short wavelength light, but a corresponding light-transmission preventing film is not formed in a part of the front surface of the semiconductor substrate 1 located above the light receiving part 2b which absorbs long wavelength light. Thus, even when long wavelength light is transmitted through the light receiving part 2b and is reflected by the wiring films 9 in the wiring layer 8, the light is blocked by the light-transmission preventing film made of the metal film 25 located above the light receiving part 2a, so that the light cannot enter the light receiving part 2a. Therefore, optical crosstalk can be reduced. Also, this structure is particularly effective when a chip having a thickness (for example, a thickness larger than 1 μm) which does not allow short wavelength light for which the semiconductor substrate 1 has a large absorption coefficient to reach the wiring layers 8 and 11 is used.

As a method for selectively forming a light-transmission preventing film above the light receiving part 2a, first, the above-described read transistor (including the gate insulating film 5a, the gate electrode 5b, the sidewalls 6, and the drain layer 4) is formed on the front surface of the semiconductor substrate 1 in which the light receiving parts 2a and 2b are formed using a known method. Subsequently, a resist pattern having openings corresponding to the light receiving parts 2a and 2b is formed over the semiconductor substrate 1 using lithography, and then, boron is ion-implanted into the semiconductor substrate 1 using the resist pattern, the gate electrode 5b, and the sidewalls 6 as an implantation mask, thereby forming a p-type front surface layer in parts of the semiconductor substrate 1 located over the light receiving parts 2a and 2b.

Thereafter, a silicidation-preventing film made of a silicon oxide film is selectively formed in a part of the semiconductor substrate 1 located above the light receiving part 2b using CVD, lithography, and etching. Then, a metal film made of, for example, Ni, etc. is deposited over the semiconductor substrate 1 using, for example, sputtering, etc., and thermal treatment is performed for 10 seconds in an N₂ atmosphere at 400-500° C., so that a light-transmission preventing film made of a silicide layer is formed only in the part of the semiconductor substrate 1 located above the light receiving part 2a. Note that an unreacted part of the metal film on the silicidation-preventing film is removed by etching.

Note that, as opposed to the above-described first and second example embodiments, in the wiring layers 8 and 11 of this example embodiment, regions of the wiring layers 8 and 11 in which the wiring films 9 and 12 are not formed to be uniform. This example embodiment can be applied to the first and second example embodiments, and the variations of the first and second example embodiments.

Note that, in this example embodiment, if color filters in respective upper parts of pixels provided in the chip are set so that each of the color filters mainly detects one of red light (with a wavelength of about 650 nm), blue light (with a wavelength of about 450 nm), and green light (with a wavelength of about 530 nm), the photodiodes which detect short wavelength light are photodiodes in blue pixels, or blue and green pixels, whose mainly detected light has a shorter wavelength than wavelengths of light beams mainly detected by other pixels. Similarly, even when pixels which mainly detect white light (any visible light) are provided in the chip, the photodiodes which detect short wavelength light are photodiodes in blue pixels or blue and green pixels.

Note that, when viewed from the top, the size of each of the light receiving parts 2a and 2b is, in general, about 1 μm×1 μm, and the area of the light-transmission preventing film made of the metal film 25 is preferably 50% or more of the area of each of the light receiving parts 2a and 2b, and is more preferably 80-100% thereof.

Note that the metal film 25 may be divided into a plurality of pieces.

As described above, according to each example embodiment of the present invention, optical crosstalk can be reduced, and thus, each embodiment of the present invention is useful to a method for forming a solid-state imaging device with backside illumination, etc.

What is claimed is:

1. A semiconductor device including an imaging area in which a plurality of pixels, each including a light receiving part which performs photoelectric conversion of incident light entering through a first surface of a semiconductor substrate, are arranged in a matrix, comprising:
a first interlevel insulating film formed over a second surface of the semiconductor substrate which is an opposite surface to the first surface; and
a first wiring layer including a plurality of first wiring films formed in the first interlevel insulating film,
wherein
in the first wiring layer, a first region which is made of the first interlevel insulating film and in which the first wiring films are not provided is formed to be located above a first light receiving part of the plurality of light receiving parts, and a second region which is made of the first interlevel insulating film and in which the first wiring films are not provided is formed to be located above a second light receiving part of the plurality of light receiving parts which is adjacent to the first light receiving part, and
a space between ones of the first wiring films with the first region interposed therebetween is larger than a space between ones of the first wiring films with the second region interposed therebetween.

2. The semiconductor device of claim 1, further comprising:
a second wiring layer which includes a plurality of second wiring films and is formed in a second interlevel insulating film provided above the first interlevel insulating film,
wherein
in the second wiring layer, a third region which is made of the second interlevel insulating film and in which the plurality of the second wiring films are not provided is formed to be located above the first light receiving part, and
a space between ones of the second wiring films with the third region interposed therebetween is larger than the space between the ones of the first wiring films with the first region interposed therebetween.

3. The semiconductor device of claim 1, further comprising:
a second wiring layer which includes a plurality of second wiring films and is formed in a second interlevel insulating film provided above the first interlevel insulating film,
wherein
in the second wiring layer, a third region which is made of the second interlevel insulating film and in which the plurality of the second wiring films are not provided is formed to be located above the first light receiving part, and
a space between ones of the second wiring films with the third region interposed therebetween is equal to or smaller than the space between the ones of the first wiring films with the first region interposed therebetween.

4. The semiconductor device of claim 1, wherein
a light blocking film which is not electrically connected is formed in the second region.

5. The semiconductor device of claim 1, wherein
a relative position of the first region to the first light receiving part in an end part of the imaging area is the same as a relative position of the first region to the first light receiving part in a center part of the imaging area.

6. The semiconductor device of claim 1, wherein
a relative position of the first region to the first light receiving part in an end part of the imaging area is shifted, as compared to a relative position of the first region to the first light receiving part in a center part of the imaging area, in a direction from the center part to the end part.

7. The semiconductor device of claim 1, wherein
a light-transmission preventing film is formed in a part of the front surface of the semiconductor device located above the second light receiving part.

8. The semiconductor device of claim 7, wherein
the light-transmission preventing film is a silicide film.

9. The semiconductor device of claim 1, wherein
the first light receiving part performs photoelectric conversion of relatively long wavelength light, and
the second light receiving part performs photoelectric conversion of relatively short wavelength light.

10. The semiconductor device of claim 9, wherein
the relatively long wavelength light is red light, and
the relatively short wavelength light is blue or green light.

11. A semiconductor device including an imaging area in which a plurality of pixels, each including a light receiving part which performs photoelectric conversion of incident light entering through a first surface of a semiconductor substrate, are arranged in a matrix, comprising:
a first interlevel insulating film formed over a second surface of the semiconductor substrate which is an opposite surface to the first surface; and
a first wiring layer including a plurality of first wiring films formed in the first interlevel insulating film,
wherein
in the first wiring layer, a first region which is made of the first interlevel insulating film and in which the first wiring films are not provided is formed to be located above a first light receiving part of the plurality of light receiving parts, and
a relative position of the first region to the first light receiving part in an end part of the imaging area is shifted, as compared to a relative position of the first region to the first light receiving part in a center part of the imaging area, in a direction from the center part to the end part.

12. The semiconductor device of claim 11, wherein
in the first wiring layer, a second region which is made of the first interlevel insulating film and in which the first wiring films are not provided is formed to be located above a second light receiving part of the plurality of light receiving parts which is adjacent to the first light receiving part, and
a light blocking film which is not electrically connected is formed in the second region.

13. The semiconductor device of claim 11, further comprising:
a second wiring layer which includes a plurality of second wiring films and is formed in a second interlevel insulating film provided above the first interlevel insulating film,
wherein
in the second wiring layer, a third region which is made of the second interlevel insulating film and in which the plurality of the second wiring films are not provided is formed to be located above the first light receiving part, and
a relative position of the third region to the first light receiving part in an end part of the imaging area is shifted, as compared to a relative position of the third region to the first light receiving part in a center part of the imaging area, in a direction from the center part to the end part.

14. The semiconductor device of claim 13, wherein
an amount of a shift of the relative position of the third region is larger than an amount of a shift of the relative position of the first region.

15. The semiconductor device of claim 11, wherein
a light-transmission preventing film is formed in a part of the front surface of the semiconductor device located above the second light receiving part.

16. The semiconductor device of claim 15, wherein
the light-transmission preventing film is a silicide film.

17. The semiconductor device of claim 12, wherein
the first light receiving part performs photoelectric conversion of relatively long wavelength light, and
the second light receiving part performs photoelectric conversion of relatively short wavelength light.

18. A semiconductor device including an imaging area in which a plurality of pixels, each including a light receiving part which performs photoelectric conversion of incident light entering through a first surface of a semiconductor substrate, are arranged in a matrix, comprising:
an interlevel insulating film formed over a second surface of the semiconductor substrate which is an opposite surface to the first surface, and
a wiring layer including a plurality of wiring films formed in the interlevel insulating film,
wherein
in the wiring layer, a first region which is made of the interlevel insulating film and in which the wiring films are not provided is formed to be located above a first light receiving part of the plurality of light receiving parts, and a second region which is made of the interlevel insulating film and in which the wiring films are not provided is formed to be located above a second light receiving part of the plurality of light receiving parts which is adjacent to the first light receiving part, and
a light-transmission preventing film is formed in a part of the front surface of the semiconductor device located above the second light receiving part.
